(19) United States
(12) Patent Application Publication
(10) Pub. No.: US 2026/0258549 A1
(43) Pub. Date: Sep. 3, 2026

(54) SOLID MATERIAL CONTAINER, SOLID MATERIAL SUPPLY DEVICE, AND SOLID MATERIAL SUPPLY METHOD

(71) Applicant: TAIYO NIPPON SANSO CORPORATION, Tokyo (JP)

(72) Inventors: Yosuke MUKAI, Tokyo (JP); Takashi KAMEOKA, Tokyo (JP); Ryoma WATANABE, Tokyo (JP); Sota KAGAWA, Tokyo (JP)

(21) Appl. No.: 18/866,271

(22) PCT Filed: Jun. 27, 2023
(86) PCT No.: PCT/JP2023/023795

§ 371 Date: Nov. 15, 2024

(30) Foreign Application Priority Data
Jul. 7, 2022 (JP) 2022-109893

(51) Int. Cl. C23C 16/455; C23C 16/52

(52) U.S. Cl. CPC C23C 16/455; C23C 16/52

(57) ABSTRACT

One object of the present application is to provide a solid material container that makes it possible to determine the remaining amount of a solid material in a container under standard conditions. The present invention provides a solid material container (11) including: a bottomed cylindrical container body (11A) having a body portion (14) with a central axis (C) extending vertically; a lid (11B) that closes a top surface, which is an opening of the container body (14); and a plurality of thermocouples (15), wherein the thermocouples (15) are inserted horizontally from the outer periphery of the body portion (14) toward the center, and the tip of the thermocouple (15) is located at the center of the body portion (14), and wherein the plurality of thermocouples (15) is arranged at two or more different heights at intervals in the vertical direction of the container body (14).

### TECHNICAL FIELD

The present invention relates to a solid material container, a solid material supply device, and a solid material supply method.

### BACKGROUND ART

In recent years, in order to solve problems caused by miniaturization and high integration of semiconductor devices, new film formation techniques using precursor materials that have not been used in the past have been required. Conventionally, gaseous and liquid materials that are relatively easy to handle have been widely used as precursor materials. On the other hand, some of the inorganic metal compounds and organometallic compounds such as aluminum, hafnium, indium, molybdenum, tantalum, titanium, tungsten, yttrium, and zirconium used in cutting-edge devices are solid at standard temperature and standard pressure. Precursor materials that are solid at standard temperature and standard pressure (hereinafter referred to as “solid materials”) cannot be directly transported to a chamber for a film formation process. These solid materials generally have high melting points and low vapor pressures, so the solid materials need to be sublimated prior to being introduced into the film formation chamber.

Incidentally, the solid material is contained in an airtight container (solid material container), and in the solid material supply device, the solid material is sublimated in the solid material container and supplied into a chamber for a film formation process. Therefore, in the solid material supply device, it is necessary to know the amount of the solid material used and to know the timing of container replacement. Therefore, it is necessary to know the remaining amount of the solid material in the solid material container with some degree of accuracy.

As a method for determining the amount of the solid material remaining in the solid material container, a weight measurement method and a method for directly measuring the temperature of a solid material are known. However, the weight measurement method does not allow the height of the remaining solid material in the solid material container to be determined.

As the method for directly measuring the temperature of a solid material, Patent Document 1 discloses a technique for directly measuring the temperature of a solid material in a solid material container. Specifically, FIG. 11 of Patent Document 1 discloses a configuration of a solid material container in which a thermocouple extending in the vertical direction is inserted in the top plate of the solid material container, and a plurality of sensors are provided at required intervals in the vertical direction on the thermocouple inside the solid material container.

### PRIOR ART DOCUMENTS

### Patent Documents

Patent Document 1 Japanese Unexamined Patent Application, First Publication No. 2012-052669

### SUMMARY OF INVENTION

### Problem to be Solved by the Invention

However, in the technology disclosed in Patent Document 1, the thermocouple itself generates heat, causing the solid material near the thermocouple to sublime first, and there is no material near the thermocouple. As a result, the temperature of the gas phase is measured instead of the solid material, which poses a problem in that it is not possible to properly monitor the remaining amount.

The present invention has been made in consideration of the circumstances above, and an object of the present invention is to provide a solid material container, a solid material supply device, and a solid material supply method that make it possible to determine the remaining amount of a solid material in a container under standard conditions.

### Means for Solving the Problem

In order to solve the above problems, the present invention has the following aspects.

[1] A solid material container that contains a solid material at normal temperature and pressure (25° C., 1 atm) and supplies gas produced by volatilization or sublimation of the solid material in accordance with the vapor pressure,
wherein the solid material container includes:
a bottomed cylindrical container body having a body portion with a central axis extending vertically;
a lid that closes a top surface, which is an opening of the container body; and
a plurality of thermocouples,
wherein the thermocouples are inserted horizontally from the outer periphery of the body portion toward the center, and the tip of the thermocouple is located at the center of the body portion, and
wherein the plurality of thermocouples is arranged at two or more different heights at intervals in the vertical direction of the body portion.

[2] The solid material container according to [1], wherein the plurality of thermocouples is arranged on the same line extending vertically in the body portion.

[3] The solid material container according to [1] or [2], wherein the solid material container further includes a heater that heats the container body, and wherein the heater being capable of heating two or more regions divided vertically.

[4] The solid material container according to [3], wherein the heater is positioned around the container body.

[5] A solid material supply device that supplies gas produced by volatilization or sublimation of a solid material at normal temperature and pressure (25° C., 1 atm) in accordance with vapor pressure including:
one or more solid material containers according to any one of [1] to [4]; and
one or more connecting pipes communicating with the solid material containers.

[6] A solid material supply method that uses the solid material supply device according to [5] to supply gas produced by volatilization or sublimation of a solid material at normal temperature and pressure (25° C., 1 atm) in accordance with the vapor pressure,
wherein the solid material supply method includes:
measuring a temperature of the solid material in the solid material container using a plurality of thermocouples arranged vertically in the solid material container that supplies gas; and
detecting a remaining amount of the solid material in the solid material container.

[7] The solid material supply method according to [6], wherein a heated area of the solid material container is changed depending on a detected remaining amount of the solid material in the solid material container.

[8] The solid material supply method according to [6] or [7], wherein when a temperature difference between a temperature of the solid material closest to the bottom surface of the solid material container and the sublimation point of the solid material becomes 20° C. or more, it is determined that the remaining amount of the material is low.

### Effects of the Invention

The solid material container of the present invention makes it possible to know the remaining amount of the solid material in the solid material container under standard conditions.

The solid material supply device and solid material supply method of the present invention make it possible to know the remaining amount of the solid material in the solid material container under standard conditions.

### BRIEF DESCRIPTION OF THE DRAWINGS

FIG. 1 is a schematic diagram of a solid material supply device according to one embodiment of the present invention.

FIG. 2 is a schematic cross-sectional view of a solid material container according to one embodiment of the present invention.

FIG. 3 is a diagram showing a mantle heater provided in a solid material container of the present embodiment, where (A) is a plan view, (B) is a front view, and (C) is a side view.

FIG. 4 is a schematic cross-sectional view of a solid material container used in an example of the present invention.

FIG. 5 is a diagram showing the results of an example.

FIG. 6 is a diagram showing the results of a comparative example.

FIG. 7 is a diagram showing the results of a comparative example.

### DETAILED DESCRIPTION OF THE PREFERRED EMBODIMENTS

Embodiments of the present invention will be described in detail below with reference to the drawings.

In the drawings used in the following description, the dimensions of the components may be shown at different scales to make each component easier to see, and the dimensional ratios of each component may not necessarily be the same as in reality. Furthermore, the materials and dimensions exemplified in the following description are merely examples, and the present invention is not necessarily limited to them, and can be modified as appropriate without departing from the gist of the invention.

### Solid Material Supply Device

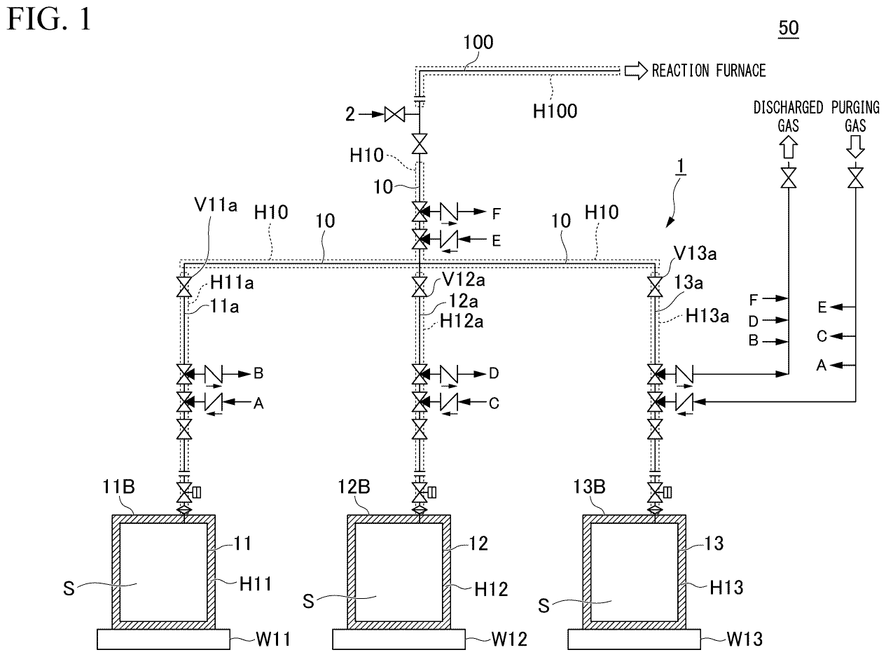

First, as one embodiment of the present invention, a solid material supply device 50 shown in FIG. 1 will be described.

Note that FIG. 1 is a system diagram that shows a schematic configuration of the solid material supply device 50, which is one embodiment of the present invention.

As shown in FIG. 1, the solid material supplying device 50 of the present embodiment is a device that supplies gas (hereinafter sometimes simply referred to as “solid material vapor”) produced by volatilization or sublimation of a solid material S at normal temperature and pressure (25° C., 1 atm) (hereinafter sometimes simply referred to as “solid material”) in accordance with vapor pressure into a reaction furnace.

The solid material supplying device 50 of the present embodiment is generally configured to include collection containers 1 and 2, a crossover pipe 100 which is connected to the collection containers 1 and 2, and a first heater H100 which heats the crossover pipe 100.

The crossover pipe 100 is a pipe that connects each of the collection containers 1, 2 with the reactor.

The solid material supplying device 50 of the present embodiment will be described as having two collection containers 1, 2 as an example, but is not limited to the present embodiment. The number of collection containers may be one, or three or more. From the viewpoint of controllability and the influence of the occurrence of a malfunctions, it is preferable that the number of collection containers be three or less.

The collection container 1 has three solid material containers 11, 12, and 13 and contains a solid material S, connecting pipes 11a, 12a, and 13a communicating with each of the solid material containers 11, 12, and 13, and a collection pipe 10 communicating with the solid material containers 11, 12, and 13 via each of the connecting pipes 11a, 12a, and 13a.

The collection pipe 10 is provided with a heater H10 that heats the entire collection pipe 10, and ports E and F that purge.

In the solid material supplying device 50 of the present embodiment, an embodiment in which the collection container 1 has three solid material containers will be described as an example, but is not limited to this embodiment. The number of the solid material containers may be one or three or more. From the viewpoint of controllability and the influence of the occurrence of a malfunction, it is preferable that the number of the solid material containers be nine or less.

The solid material S is not particularly limited as long as it is a material that is in a solid state at normal temperature and pressure (25° C., 1 atm). The solid material S may be in a crystalline or powdered state, or may be supported on a support or the like. The solid material S may be in a solid state when filled, may be in a solid state when transported, or may be in a liquid state when filled or heated.

Examples of the solid material S include organic compounds, organometallic compounds, metal halides, metal oxyhalides, and mixtures thereof. More specifically, examples of the solid material S include inorganic metal compounds and organometallic compounds such as germanium, gallium, aluminum, hafnium, indium, molybdenum, tantalum, titanium, tungsten, yttrium, and zirconium.

The solid material S may be any one of these compounds, or may contain two or more thereof.

### Solid Material Container

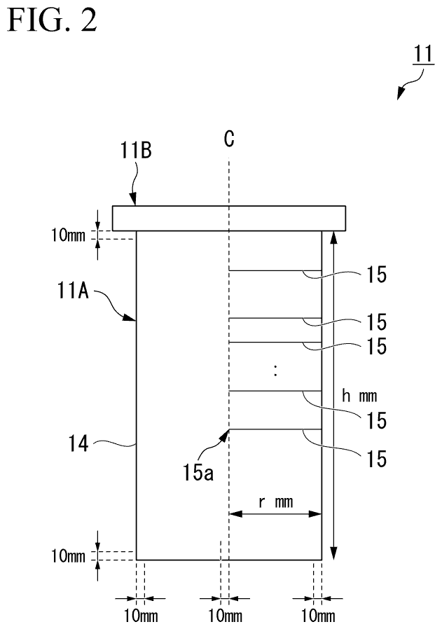

Next, the configuration of the solid material container, which is one embodiment of the present invention, will be described using a solid material container 11 as an example. FIG. 2 is a schematic cross-sectional view for explaining the configuration of the solid material container 11 of the present embodiment.

As shown in FIG. 2, the solid material container 11 includes a bottomed cylindrical container body 11A, a lid 11B, and a plurality of thermocouples 15, 15 . . . 15 that monitor the internal temperature of the solid material container 11.

The solid material container 11 is not particularly limited as long as it is a container capable of being filled with the solid material S. Specifically, the solid material container 11 can be used repeatedly by supplying the solid material S inside in a gaseous state and then adding the solid material S again inside.

The container body 11A is not particularly limited, but is preferably a cylindrical container with a bottom from the viewpoint of adding the inside with the solid material S. Specifically, the container body 11A has a body portion 14 having a central axis C extending in the vertical direction.

A plurality of thermocouples 15 are inserted horizontally from the outer periphery of the container body 11A toward the center of the body portion 14. When the container body 11A is cylindrical with a bottom, the plurality of thermocouples 15 are inserted horizontally radially toward the center. Tips 15a of the thermocouples 15 serve as temperature measurement portions.

The tip 15a of thermocouple 15 is located inside and at the center of the body portion 14. In the present description, the center of the body portion 14 means a region that includes the central axis C of the body portion 14 and includes a required range from the central axis C. Since the temperature measurement portion, which is the tip 15a of thermocouple 15, is located at the center of the body portion 14 (i.e., container body 11A), it is less susceptible to the effect of heat from the outer periphery of container body 11A, and the temperature of the solid material S can be accurately measured.

The length of the thermocouple 15 inserted inside the body portion 14 of the container body 11A can be, for example, “r±10” mm, where the radius of the inner diameter of the container body 11A is “r” mm.

Furthermore, the plurality of thermocouples 15 inserted into the body portion 14 is arranged at two or more different heights with the required intervals in the vertical direction of the body portion 14.

It is preferable to arrange two or more thermocouples 15 inserted into the body portion 14, and it is more preferable to arrange three or more in the vertical direction from the viewpoint of monitoring the remaining amount of the solid material S in the container body 11A (i.e., the solid material container 11).

Furthermore, the intervals at which the plurality of thermocouples is installed in the vertical direction are not particularly limited. Furthermore, the intervals at which the plurality of thermocouples is installed in the vertical direction may be equal or unequal. It is preferable to install the plurality of thermocouples in the vertical direction at equal intervals, since this allows for appropriate remaining amount monitoring (e.g., 50% remaining, 30% remaining, and the like).

The height (h) of the thermocouple 15 inserted inside the body portion 14 of the container body 11A in the axial direction of the body portion 14 is preferably set at a position 7 mm to 13 mm from the bottom and top surfaces (underside of the lid) of the body portion 14. This makes it less susceptible to the effects of heat from the outer periphery (top and bottom surfaces) of the container body 11A, and allows the temperature of the solid material S to be measured accurately.

The height (h) of the thermocouple 15 can be appropriately selected taking into consideration the thermal conductivity of the materials constituting the body portion 14 and the lids 11B, 12B, and 13B.

The lid 11B closes the top surface, which is the opening of the container body 11A. The lid 11B is removable from the container body 11A. When the amount of the solid material remaining in the solid material container 11 becomes low, the solid material can be replenished into the container body 11A through the opening of the top surface by removing the lid 11B from the container body 11A.

As shown in FIG. 1, the connecting pipe 11a is provided on the lid 11B of the solid material container 11. The connecting pipe 11a is also provided with an on-off valve V11a that can be remotely controlled and can be adjusted to any opening degree from fully open (100% opening) to fully closed (0% opening).

The connecting pipe 11a is provided with a heater H11a that heats the connecting pipe 11a, and ports A and B that purge.

The material of the solid material container 11 is not particularly limited, but is preferably a material with high thermal conductivity in order to improve the efficiency of heat transfer to the solid material S. Examples of such materials include stainless steel, aluminum, silicon carbide, aluminum nitride, aluminum oxide, and silicon nitride.

In addition to the heat transfer efficiency, the solid material container 11 may be required to have corrosion resistance and strength. When a plurality of properties are required for the solid material container 11, the solid material container 11 may be configured by laminating a plurality of materials.

The material of the thermocouple 15 is not particularly limited as long as it has corrosion resistance and strength. Examples of such materials include SUS316L, SUS316, and SUS304.

The solid material container 11 further includes a heater H11 that heats the solid material S filled inside the solid material container 11, and a weight measuring device W11 that monitors the weight of the solid material container 11.

The heater H11 is not particularly limited as long as it can heat the solid material S in the solid material container 11, and can be appropriately selected from types that heat the solid material container 11 from the outside (e.g., mantle heater, thermostatic bath, high-frequency heating device, and the like) and types that heat the solid material container 11 from the inside (e.g., rod heater, and the like). These types may also be used in combination. Among these, the type that heats the solid material container 11 from the outside is preferred because it is not affected by the solid material stored inside, and a mantle heater that is positioned around the solid material container 11 and covers and heats the solid material container 11 is more preferred.

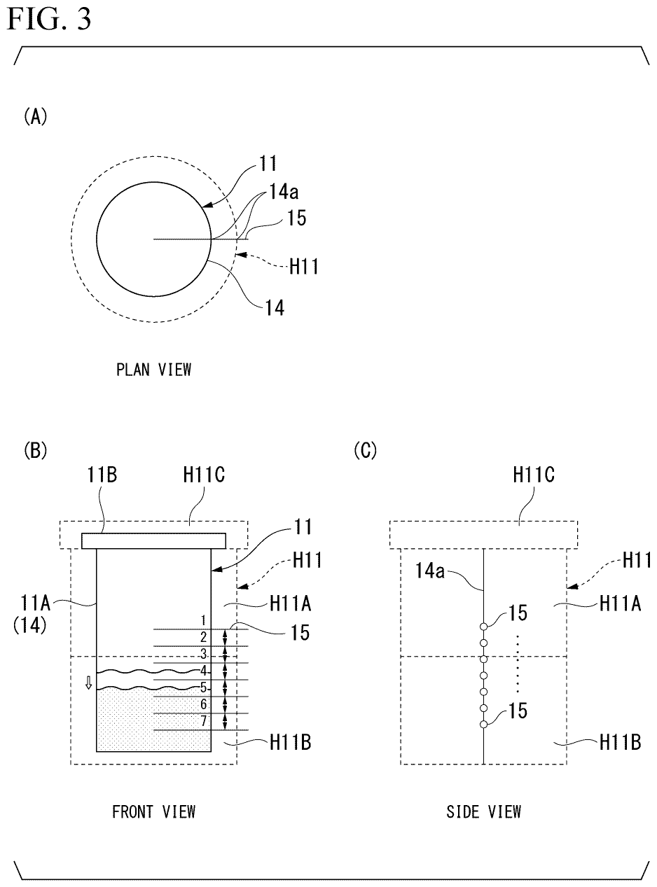

FIG. 3 shows the mantle heater H11 provided in the solid material container 11 of the present embodiment, where (A) is a plan view, (B) is a front view, and (C) is a side view.

As shown in FIG. 3(B) and 3(C), the mantle heater H11 is disposed so as to cover the periphery of the solid material container 11, and has heaters H11A and H11B that heat the container body 11A, and a heater H11C that heats the lid 11B.

The heaters H11A and H11B are divided in the vertical direction, so that the heaters H11A and H11B can independently heat two regions divided in the vertical direction of the container body 11A.

According to the solid material container 11 of the present embodiment, the heating state of the heaters H11A and H11B (i.e., the region to be heated in the container body 11A) can be independently selected in conjunction with monitoring of the remaining amount of the solid material S by the thermocouple 15. For example, when the solid material container 11 is sufficiently filled with the solid material S, the heaters H11A and H11B heat two regions divided in the vertical direction of the container body 11A, respectively. Then, when the supply of the solid material S progresses and it is determined that the solid material S in the solid material container 11 is less than half full, the heater H11A is stopped, and only the region divided in the vertical direction of the container body 11A can be heated by the heater H11B.

In this way, the vertically divided heaters H11A and H11B can independently heat the two vertically divided areas of the solid material container 11 (container body 11A), thereby preventing the upper portion of the solid material container 11 from heating empty when the remaining amount of the solid material S is small.

Furthermore, as shown in FIG. 3(A) and 3(C), when covering the periphery of the container body 11A with the mantle heater H11, if the heaters H11A, H11B are strip-shaped and are installed by wrapping them around the periphery of the container body 11A, it is preferable that the overlapping positions of both ends of the heaters H11A, H11B be on the same line as a line 14a extending vertically of the body portion 14 of the container body 11A. It is preferable to arrange the insertion positions of the body portion 14 of the plurality of thermocouples 15 on the same line as the above-mentioned line 14a. By arranging the heaters H11A, H11B and the plurality of thermocouples 15 on the outer periphery of the container body 11A in this way, the plurality of thermocouples 15 and the heaters H11A, H11B can be arranged without interfering with each other.

The same applies to the solid material containers 12, 13.

A method of disposing the solid material S in the container body 11A will be described below.

The thermocouple 15 is placed in the thermocouple insertion hole 15A provided in the container body 11A. At this time, it is preferable to insert the thermocouple 15 so that the tip of the thermocouple 15 reaches the center of the container body 11A.

The solid material S is then placed inside the container body 11A. At this time, there may be a space between the solid material S and the inner wall of the container body 11A.

The solid material S can also be heated to become a liquid, and the liquid obtained can be poured into the container body 11A with the thermocouple 15 inserted and then solidified.

After the solid material S has been placed in the container body 11A, the upper opening of the container body 11A is sealed with the lid 11B. Next, the heater 11H is placed around the container body 11A.

### Solid Material Supply Method

Next, a solid material supply method using the solid material supply device 50 of the present embodiment will be described.

### (Normal Operation)

First, the crossover pipe 100 of the solid material supply device 50 is connected to the reactor, which is the use point.

Next, in order to vaporize the solid material S, operation of the heaters H11, H12, and H13 of the collection container 1, which supplies the solid material vapor, is started, and heating of the solid material containers 11, 12, and 13 is started.

Next, after the temperature and pressure in the solid material containers 11, 12, and 13 of the selected collection container 1 reach the set values and a predetermined stabilization time has elapsed, the solid material vapor can be supplied to the use point by remotely opening the on-off valves installed in each pipe.

Next, after the supply of the solid material S is completed, the solid material vapor remaining in the pipe of all the collection containers 1 is discharged and purged. Finally, the on-off valves installed in each pipe are closed by remote control to terminate the supply of the solid material.

In the solid material supplying method of the present embodiment, when controlling the above-mentioned normal operation, the remaining amount of the solid material S in each of the solid material containers 11, 12, 13 is monitored.

### (Monitoring the Remaining Amount of Solid Material in Container)

In the solid material supply method of the present embodiment, a plurality of thermocouples 15 is arranged vertically in each of the solid material containers 11, 12, and 13 to measure the temperature of the solid material S in each container and detect the remaining amount of the solid material S in the container. This makes it possible to prevent the solid material in the solid material container from overheating, and allows the solid material supply container to be replaced at the appropriate time.

The following will take the case of the solid material container 11 as an example.

Specifically, the temperature of each of the plurality of thermocouples 15 spaced apart in the vertical direction of body portion 14 of the solid material container 11 is measured. Then, the temperature difference between the temperature at each height of the solid material container 11 and the sublimation point of the solid material S is calculated. It is determined that the solid material S remains at the height where thermocouples 15 have a temperature difference of less than 20° C. In contrast, it is determined that no solid material S remains at the height where the thermocouples 15 have a temperature difference of 20° C. or more. In this way, the remaining amount of the solid material S in solid material container 11 can be monitored.

Similar monitoring is also performed for solid materials 12 and 13.

In addition, in the solid material supply method of the present embodiment, when gas of the solid material S is supplied from the solid material container 11, the operation of the mantle heater H11 is started. The remaining amount of the solid material S in the solid material container 11 is monitored, and when the height of the solid material S in the container decreases and becomes below the area covered by the heater H11A, heating by the heater H11A can be stopped. In this way, by changing the heating area of the solid material container 11 in accordance with the detected remaining amount of the solid material S in the container, it is possible to prevent the solid material container 11 from heating empty and reduce energy consumption.

Furthermore, in the solid material supply method of the present embodiment, it is determined that the remaining amount of the solid material S in the container is low when the temperature difference between the temperature measured by the thermocouple 15 arranged at the position closest to the bottom surface of the solid material container 11 and the sublimation point of the material becomes 20° C. or more. This allows the replacement of a solid material supply container in which the remaining amount of the solid material S in the container is low to be carried out at an appropriate time, thereby enabling a stable supply of gas of the solid material S.

As described above, according to the solid material container 11 of the present embodiment, the plurality of thermocouples 15 inserted into the body portion 14 of the container body 11A is arranged at two or more different heights at required intervals in the vertical direction of the body portion 14. This allows the temperature to be measured at a plurality of positions in the vertical direction of the container body 11A, and the positions where the solid material S remains and the positions where the solid material S does not remain can be identified from the temperature difference, making it possible to monitor the remaining amount of the solid material S in the solid material container 11.

Moreover, according to the solid material container 11 of the present embodiment, the plurality of thermocouples 15 is inserted horizontally from the body portion 14, which is the side surface of the container body 11A. As a result, even if the solid material S is sublimated by heating with the thermocouple 15 and a gap is formed around the thermocouple 15, the gap is filled by the weight of the solid material S, so that the temperature of the solid material S can be accurately measured as long as the solid material S is at the same height as the thermocouple 15. As a result, it is possible to monitor the remaining amount of the solid material S in the solid material container 11.

The solid material supplying device 50 and the solid material supplying method of the present embodiment include the solid material containers 11, 12, and 13, and the connecting pipes 11a, 12a, and 13a each of which communicates with the solid material containers 11, 12, and 13. This makes it possible to monitor the remaining amount of the solid material S in each of the solid material containers 11, 12, and 13, and therefore to replace a solid material supplied into the container in which the remaining amount of the solid material S in the container has decreased at an appropriate timing.

Furthermore, according to the solid material supplying device 50 and the solid material supplying method of the present embodiment, solid materials that are solid at standard temperature and pressure, including inorganic and organic metal compounds of germanium, gallium, aluminum, hafnium, indium, molybdenum, tantalum, titanium, tungsten, yttrium, zirconium, and the like can be stably supplied in a gaseous state to a reactor for a long period of time.

The technical scope of the present invention is not limited to the above-described embodiment, and various modifications can be made without departing from the spirit of the present invention.

### EXAMPLES

The present invention will be described in more detail below using an example and a comparative example, but the present invention is not limited to the following example.

### Example

The amount of the solid material remaining in the solid material container was monitored when the solid material vapor was supplied using the solid material supply device shown in FIG. 1.

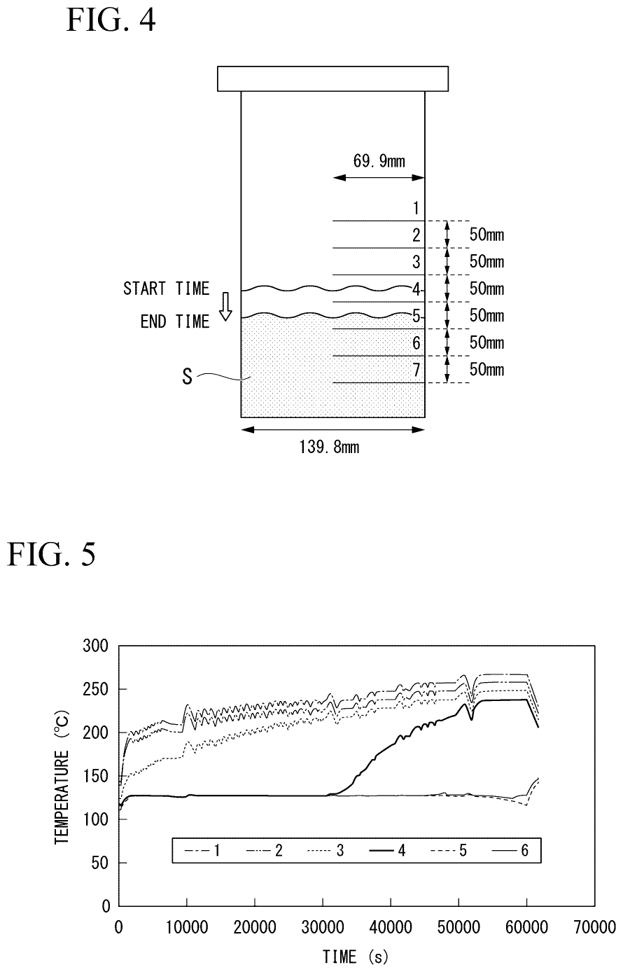

The solid material container used had the configuration shown in FIG. 4.

### (Solid Material Container)

Diameter of container body: 139.8 mm
Tip position of thermocouple in the radial direction of container body: 69.9 mm (from the peripheral wall)
Number of thermocouples: 7 installed at 50 mm intervals in the vertical direction (reference numbers 1 to 7 in FIG. 4)
Solid material: Molybdenum oxychloride (sublimation point: 130° C.), filled to a height between the third and fourth thermocouples from the top
Heating temperature: 150° C.
Gas supply time: Gas supply was started when the temperature inside the solid material container reached 130° C., and this time was designated as gas supply start time 0 (sec).

FIG. 5 shows the results of the example. In FIG. 5, the X-axis indicates the time from the start of gas supply, and the Y-axis indicates the temperature of the thermocouples located at each height in the solid material container. The numerical values for each series in FIG. 5 are the same as the symbols for the thermocouples in FIG. 4.

As shown in FIG. 5, for the first to third thermocouples from the top in the container, the temperature exceeded 150° C. immediately 0 seconds after gas supply began, and was 20° C. above the sublimation point of the solid material. As a result, it was determined that there was no solid material in the container and that the gas phase was being measured.

Furthermore, at the fourth thermocouple from the top in the container, the temperature was less than 130° C. from 0 seconds to 3,000 seconds after the gas supply started, and did not exceed 20° C. from the sublimation point of the solid material, so it was determined that it was measuring the solid material in the container.

After that, as the supply of the solid material vapor progressed and exceeded 40,000 to 50,000 seconds from the start of gas supply, the temperature of the fourth thermocouple rose and exceeded 20° C. from the sublimation point of the solid material, so it was determined that there was no solid material in the container at the height of the fourth thermocouple and that the gas phase was being measured.

In addition, for the fifth and sixth thermocouples from the top in the container, the temperature was less than 130° C. from 0 seconds after the gas supply started, and did not exceed 20° C. from the sublimation point of the solid material, so it was determined that they were measuring the solid material in the container.

According to the embodiment of the present invention, it was confirmed that the remaining amount of the solid material in the solid material container can be monitored.

### Comparative Example

Using the solid material supply device and the solid material container of the example, one thermocouple was inserted vertically from the top surface of the solid material container, and the tip of the thermocouple was positioned near the bottom of the solid material container.

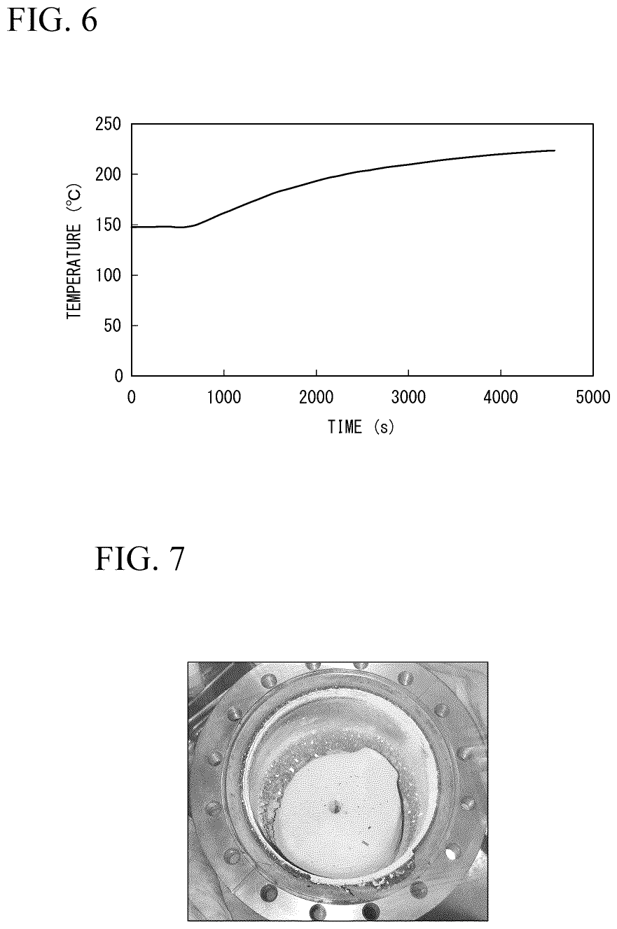

FIG. 6 shows the results of the comparative example. In FIG. 6, the X-axis indicates the time from the start of gas supply, and the Y-axis indicates the thermocouple temperature.

As shown in FIG. 6, from 0 seconds to 700 seconds after the start of gas supply, the temperature of the thermocouple was constant, and it was determined that the temperature of the solid material was being measured.

After 700 seconds had passed since the start of gas supply, the temperature of the thermocouple rose, and it was determined that there was no solid material around the thermocouple and that the gas phase was being measured.

FIG. 7 shows the results of a comparative example. Specifically, when the temperature of the thermocouple rose more than 700 seconds after the start of gas supply, the heating of the solid material container was stopped, and the state of the solid material when the lid of the solid material container was removed after the temperature had dropped to normal temperature (25° C.) is shown.

As shown in FIG. 7, when the thermocouple was inserted vertically from the top surface of the solid material container, sublimation of the solid material occurred near the thermocouple, creating a gap around the thermocouple, making it impossible to monitor the remaining amount of the solid material in the container.

### EXPLANATION OF SYMBOLS

1,2: Collection container
10: Collection pipe
11, 12, 13: Solid material supply container
11a, 12a, 13a: Connecting pipe
11A: Container body
11B: Lid
14: Body portion
14a: Straight line
15: Thermocouple
15a: Tip (temperature measurement portion)
100: Crossover pipe
50: Solid material supply device
C: Central axis
H10: Heater
H11, H12, H13: Mantle
H11a, H12a, H13a: Heater
H100: Heater
S: Solid material
V11a, V12a, V13a: On-off valve
W11, W12, W13: Weight measuring device

1. A solid material container that contains a solid material at normal temperature and pressure (25° C., 1 atm) and supplies gas produced by volatilization or sublimation of the solid material in accordance with the vapor pressure,
wherein the solid material container comprises:
a bottomed cylindrical container body having a body portion with a central axis extending vertically;
a lid that closes a top surface which is an opening of the container body; and
a plurality of thermocouples,
wherein the thermocouples are inserted horizontally from the outer periphery of the body portion toward the center, and the tip of the thermocouple is located at the center of the body portion, and
wherein the plurality of thermocouples is arranged at two or more different heights at intervals in the vertical direction of the body portion.

2. The solid material container according to claim 1,
wherein the plurality of thermocouples is arranged on the same line extending vertically in the body portion.

3. The solid material container according to claim 1,
wherein the solid material container further comprises a heater that heats the container body, and
wherein the heater is capable of heating two or more regions divided vertically.

4. The solid material container according to claim 3,
wherein the heater is positioned around the container body.

5. A solid material supply device that supplies gas produced by volatilization or sublimation of a solid material at normal temperature and pressure (25° C., 1 atm) in accordance with vapor pressure, comprising:
one or more solid material containers according to claim 1; and
one or more connecting pipes communicating with the solid material containers.

6. A solid material supply method that uses the solid material supply device according to claim 5 to supply gas produced by volatilization or sublimation of a solid material at normal temperature and pressure (25° C., 1 atm) in accordance with the vapor pressure,
wherein the solid material supply method comprises:
measuring a temperature of the solid material in the solid material container using a plurality of thermocouples arranged vertically in the solid material container that supplies gas; and
detecting a remaining amount of the solid material in the solid material container.

7. The solid material supply method according to claim 6,
wherein a heated area of the solid material container is changed depending on a detected remaining amount of the solid material in the solid material container.

8. The solid material supply method according to claim 6,
wherein when a temperature difference between the temperature of the solid material closest to the bottom surface of the solid material container and the sublimation point of the solid material becomes 20° C. or more, it is determined that the remaining amount of the material is low.
